(19) United States
(12) Patent Application Publication
(10) Pub. No.: US 2015/0085295 A1
(43) Pub. Date: Mar. 26, 2015

(54) LIGHT EMITTING DEVICE AND OPTICAL COHERENCE TOMOGRAPHY APPARATUS INCLUDING SAME AS LIGHT SOURCE

(71) Applicant: CANON KABUSHIKI KAISHA, Tokyo (JP)

(72) Inventors: Takeshi Yoshioka, Kawasaki-shi (JP); Takeshi Uchida, Hiratsuka-shi (JP)

(21) Appl. No.: 14/495,719

(22) Filed: Sep. 24, 2014

(30) Foreign Application Priority Data
Sep. 26, 2013 (JP) 2013-200129

(51) Int. Cl. H01L 33/00; H01L 33/58; G01B 9/02

(52) U.S. Cl. CPC H01L 33/0045; G01B 9/02091; G01B 9/02041; H01L 33/58
USPC 356/479; 257/98

(57) ABSTRACT

A light emitting device includes an optical waveguide including an active layer having at least two gain peaks and a pair of clad layers sandwiching the active layer and electrodes disposed in a guided wave direction of the optical waveguide.

The electrodes include a first electrode nearest the emitting end and a second electrode next thereto.

The light emitting device includes a grating section in the vicinity of the optical waveguide between the first and second electrodes.

The grating section reflects or absorbs a beam having a wavelength other than peak wavelengths corresponding to the two gain peaks in a spectrum of the beam generated by driving the second electrode. The beam generated by driving the second electrode and having the selected wavelength is guided to a region of the optical waveguide where the first electrode is disposed and is combined with a beam generated by driving the first electrode.

### BACKGROUND OF THE INVENTION

1. Field of the Invention

The present invention relates to a light emitting device and an optical coherence tomography apparatus including the same as a light source.

2. Description of the Related Art

A superluminescent diode (SLD), which is one type of light emitting device, is a semiconductor light source having a broadband spectral distribution, like as a light emitting diode, and capable of achieving relatively high optical power of 1 mW or more, like a semiconductor laser.

Such a SLD is attracting interest in the medical field and measurement field, where their characteristics need high resolution. The SLD is used as a light source in an optical coherence tomography apparatus that uses an optical coherence tomography (OCT) system in acquiring optical tomographic images of in vivo tissues, as disclosed in Japanese Patent Laid-Open No. 2007-212428.

A large spectral full width at half maximum is necessary to acquire a tomographic image with high resolution. Approaches to widen the spectral band have been made using various methods.

Examples of the methods may include the use of an active layer having a plurality of quantum well structures with well widths or with different composition ratios and the use of an active layer having a single quantum well structure.

With these structures, a large full width at half maximum can be accomplished by utilizing superposition of emission spectra from different energy levels.

A light source in an OCT system is required to have a satisfactory spectral shape, in addition to high power and a wide band.

In consideration of acquirement of a tomographic image by performing a Fourier transform on an acquired spectrum, it is desired that the spectral shape in the light source be unimodal, ideally, be a Gaussian function shape. This can reduce the occurrence of pseudo signals in images and thus can provide high-quality images.

FIG. 14 illustrates emission spectra in two SLDs having different cavity lengths (sample A: 0.25 mm, sample B: 0.65 mm) in the same active layer having a plurality of levels.

These two emission spectra are obtained by being set to similar current densities where emissions from the plurality of levels are observed to achieve wide bands.

A comparison of both samples illustrates that sample A has a satisfactory spectral shape, but has a small output, whereas sample B has a large output because of the long cavity length, but its spectral shape is bimodal.

The reason for being bimodal is that the amplifying effects are large in the wavelengths where the levels are present. That is, for a SLD with a single active layer, the spectral shape deteriorates when both a wide band and high power are satisfied.

### SUMMARY OF THE INVENTION

The present invention provides a light emitting device capable of achieving both a wide band and high power and acquiring a unimodal spectral shape and also provides an optical coherence tomography apparatus including the light emitting device as a light source.

A light emitting device according to an aspect of the present invention includes an optical waveguide and electrodes.

The optical waveguide includes an active layer disposed above a substrate and a pair of clad layers sandwiching the active layer.

The electrodes are disposed in a guided wave direction of the optical waveguide.

The light emitting device drives the electrodes and emits a beam guided to the optical waveguide through an emitting end of the optical waveguide.

The active layer has at least two gain peaks.

The electrodes include a first electrode nearest the emitting end and a second electrode next to the first electrode.

The light emitting device further includes a grating section disposed in a vicinity of the optical waveguide and located between the first and second electrodes.

The grating section is set so as to reflect or absorb a beam having a wavelength other than wavelengths in a portion between the two gain peaks in a spectrum of the beam generated by driving the second electrode.

The beam generated by driving the second electrode and having the wavelength selected by the grating section is guided to a region of the optical waveguide where the first electrode is disposed and is combined with a beam generated by driving the first electrode.

The light emitting device emits a beam having a peak in a dip portion between the two gain peaks in a spectrum of the beam generated by driving the first electrode through the end face.

An optical coherence tomography apparatus according to another aspect of the present invention includes a light source including the light emitting device, a specimen measuring unit, a reference unit, an interference unit, a light detecting unit, and an image processing unit.

The specimen measuring unit is configured to irradiate a specimen with a beam from the light source and transmit a beam reflected from the specimen.

The reference unit is configured to irradiate a reference mirror with the beam from the light source and transmit a beam reflected from the reference mirror.

The interference unit is configured to cause the reflected beam from the specimen measuring unit and the reflected beam from the reference unit to interfere with each other to acquire an interference beam.

The light detecting unit is configured to detect the interference beam from the interference unit.

The image processing unit is configured to acquire a tomographic image of the specimen based on the beam detected by the light detecting unit.

Further features of the present invention will become apparent from the following description of exemplary embodiments with reference to the attached drawings.

### BRIEF DESCRIPTION OF THE DRAWINGS

FIG. 1 is a perspective view that illustrates a configuration of a SLD according to a first exemplary embodiment of the present invention.

FIG. 2 is a top view that illustrates the configuration of the SLD according to the first exemplary embodiment of the present invention.

FIGS. 3A and 3B are cross-sectional views that illustrate the configuration of the SLD according to the first exemplary embodiment of the present invention and that are taken along the line IIIA-IIIA and IIIB-IIIB in FIG. 2, respectively.

FIG. 4 is a cross-sectional view that illustrates the configuration of the SLD according to the first exemplary embodiment of the present invention and that is taken along the line IV-IV in FIG. 2.

FIG. 5 is an enlarged view of an electrode separating region according to the first exemplary embodiment of the present invention.

FIG. 6 includes illustrations for describing advantages according to the first exemplary embodiment of the present invention.

FIG. 7 illustrates parameters necessary for a seed beam according to the first exemplary embodiment of the present invention.

FIG. 8 illustrates a transmittance spectrum in gratings used in a sample according to the first exemplary embodiment of the present invention.

FIG. 9 illustrates results of a measurement according to the first exemplary embodiment of the present invention.

FIG. 10 is a top view that illustrates a configuration of a SLD according to a second exemplary embodiment of the present invention.

FIG. 11 illustrates a transmittance spectrum in gratings used in a sample according to a third exemplary embodiment of the present invention.

FIG. 12 illustrates results of a measurement according to the third exemplary embodiment of the present invention.

FIG. 13 illustrates an example configuration of an optical coherence tomography apparatus that uses the SLD of the present invention according to a fourth exemplary embodiment.

FIG. 14 illustrates emission spectra in typical SLDs observed to intend to achieve a wide band.

### DESCRIPTION OF THE EMBODIMENTS

Example configurations of a light emitting device according to embodiments of the present invention are described below. As an example of the light emitting device according to the embodiments, a superluminescent diode (SLD) is described below.

The SLD according to the embodiments is configured as described below to acquire a satisfactory unimodal spectrum by using a beam having a wavelength selected in advance.

That is, the SLD according to the embodiments includes an optical waveguide and electrodes. The optical waveguide includes an active layer above a substrate and a pair of clad layers sandwiching the active layer. The electrodes are disposed in a guided wave direction of the optical waveguide. The SLD is configured to emit a beam guided to the optical waveguide from an emitting end of the optical waveguide.

The active layer has at least two gain peaks.

The electrodes include a first electrode nearest the emitting end and a second electrode next to the first electrode.

The SLD further includes a grating section disposed in the vicinity of the optical waveguide and located between the first and second electrodes.

The grating section is set so as to reflect or absorb a beam having a wavelength other than wavelengths in a portion between the two gain peaks in a spectrum of the beam generated by driving the second electrode.

The beam generated by driving the second electrode and having the wavelength selected by the grating section is guided to a region of the optical waveguide where the first electrode is disposed and is combined with a beam generated by driving the first electrode.

This enables a peak to occur in a dip portion between the two gain peaks in the spectrum of the beam generated by driving the first electrode.

Briefly, the SLD according to the embodiments includes the single active region subjected to current injection and the plurality of types of gratings disposed in the electrode separating portion that separates the first electrode and the second electrode in the guided wave direction. The beam having the wavelength selected by the gratings and having substantially the same magnitude as that in the dip portion between the two gain peaks in the spectrum of the beam generated by driving the first electrode (seed beam) compensates for the dip, thus enabling acquisition of a combined beam having a satisfactory spectral shape (beam emitted through the end face).

More specific configurations of the SLD according to the embodiments of the present invention are described below.

The active layer in the SLD according to the embodiments is a single one with a structure having a plurality of emission levels. Examples of the structure may include a multiple quantum well structure having a plurality of quantum wells having different depths and a single quantum well structure having a plurality of levels by making the depth of the well deep or narrow.

The electrodes are two electrodes separated in the guided wave direction. Different current densities can be set for the electrodes.

The first electrode has a driving condition set such that an emission spectrum has an unsatisfactory spectral shape but achieves high power and a wide band. For example, the current density may be adjusted such that emission for a first-order level and emission for a ground level are substantially equal to each other.

The second electrode has a driving condition set such that, of an optical component generated at the first electrode, a beam with a wavelength to be complemented is produced. For example, in order to complement a light emission wavelength between the first-order level and the ground level, it is necessary that emissions from both levels occur in the second electrode.

When a driving condition that satisfies both of the above conditions is used, the same current density can also be set for the first electrode and the second electrode.

The gratings are disposed in a portion of the waveguide and located between the first and second electrodes. This enables the gratings to select a wavelength of a beam generated at the second electrode, the beam with the selected wavelength (seed beam) to be guided to the first electrode, and a beam in which the guided beam is combined with a beam generated at the first electrode to be emitted through an end face.

### EXEMPLARY EMBODIMENTS

Exemplary embodiments of the present invention are described below.

### First Exemplary Embodiment

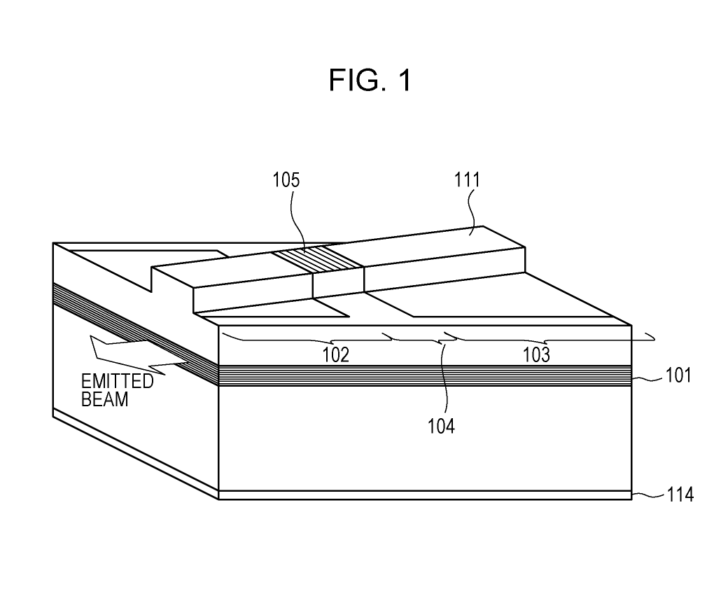

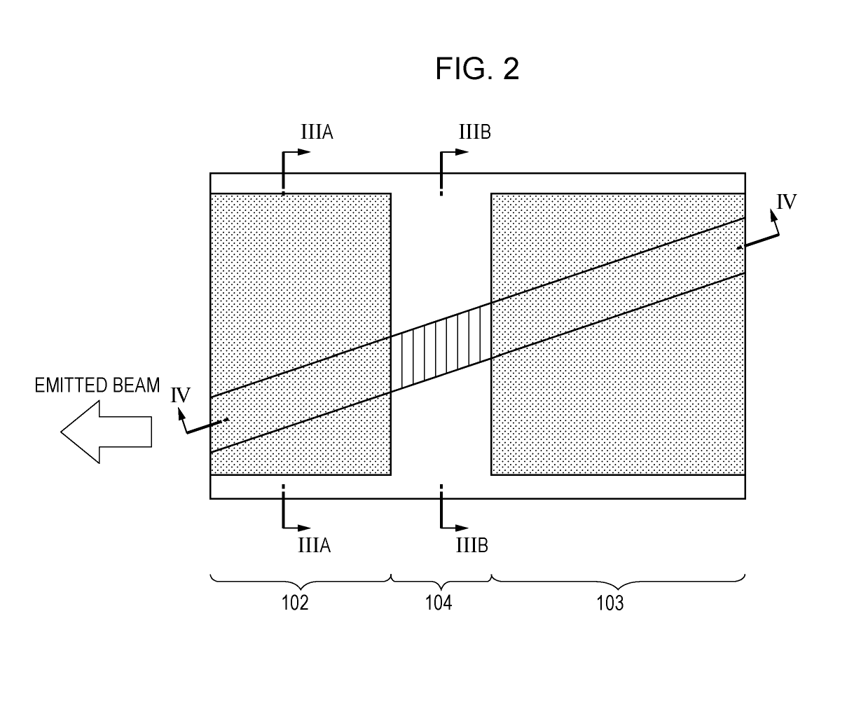

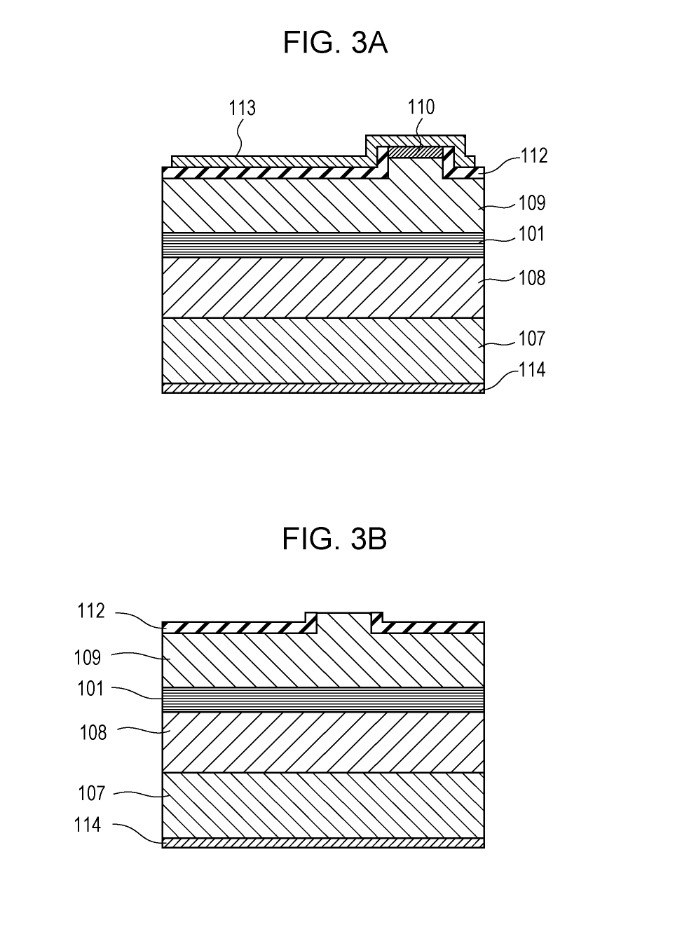

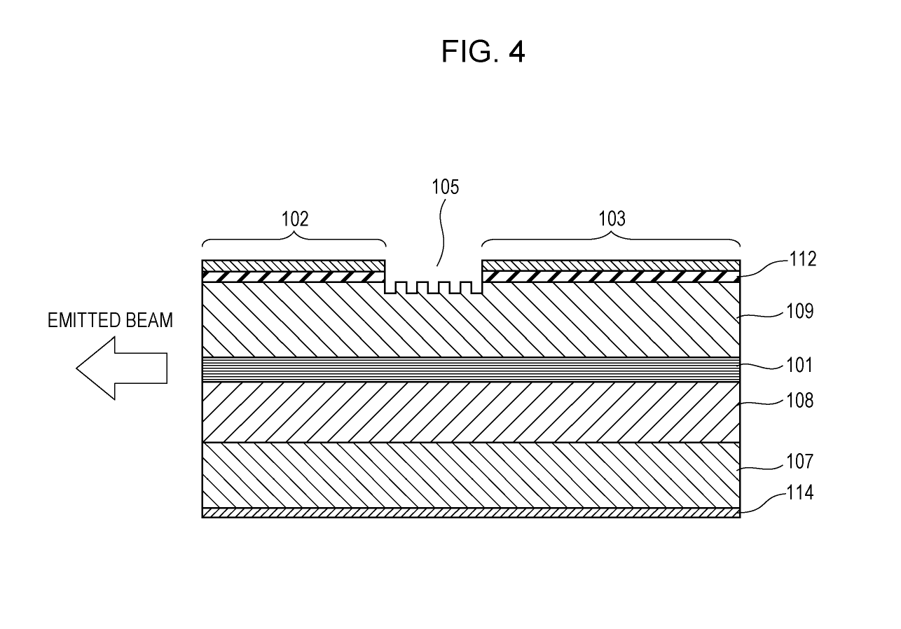

As a first exemplary embodiment, an example configuration of the SLD to which the present invention is applied is described with reference to FIGS. 1, 2, 3A, 3B, and 4.

The SLD according to the present exemplary embodiment has a ridge waveguide structure and includes a single active layer 101 spreading over the sample surface, two electrodes separated in the guided wave direction (first electrode 102 and second electrode 103), and a grating section 105 including two types of gratings disposed in an electrode separating region 104.

This configuration enables a beam emitted directly from the active region and a beam guided through the gratings from the active region to be combined with each other and the combined beam to be emitted through the end face.

In the present exemplary embodiment, an n-Al0.5 gallium arsenide (GaAs) layer as an n-type clad layer 108, an indium gallium arsenide (InGaAs) single quantum well having two emission levels as the active layer 101, an p-Al0.5 GaAs layer as a p-type clad layer 109, and a high-doped p-GaAs layer as a contact layer 110 are stacked on an n-type GaAs substrate 107.

A ridge portion 111 is formed by partially removing the contact layer 110 and the p-type clad layer 109. After the ridge portion 111 is formed, an insulating layer 112 and an upper electrode 113 are formed on the top, and a lower electrode 114 is formed on the lower surface of the substrate.

The upper electrode 113 is separated into two portions in the guided wave direction to enable emission spectra before and after the grating section 105 to be individually controlled.

Silicon dioxide (SiO₂) is used in the insulating layer 112. Titanium/gold (Ti/Au) is used in the upper electrode 113. Gold-germanium/nickel/gold (AuGe/Ni/Au) is used in the lower electrode 114.

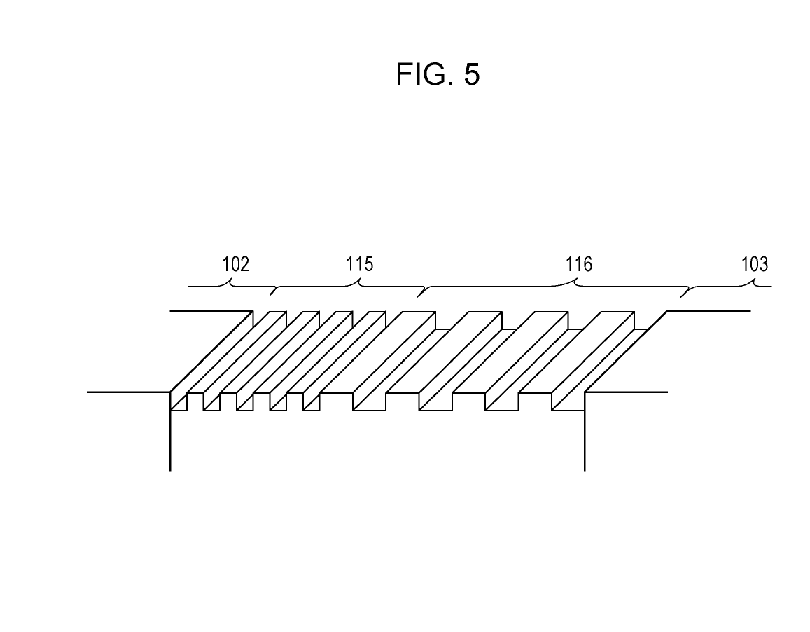

FIG. 5 illustrates an enlarged view of the electrode separating region 104.

In the present exemplary embodiment, the two types of gratings (first grating 115 and second grating 116) are disposed.

One grating is configured to reflect or absorb a beam with a wavelength shorter than a wavelength required for a seed beam. The other grating is configured to reflect or absorb a beam with a wavelength longer than the required wavelength. With this manner, the seed beam can be adjusted to have a desired peak wavelength and a peak width.

The conditions required for the seed beam are described below.

The seed beam is a beam generated at the second electrode, having a wavelength selected by the grating section 105, and then guided to the first electrode region 102.

A combination of two types of gratings having different period intervals, different numbers of periods, and different effective refractive indices is used in the wavelength selection. The two types of gratings may be interchanged in the guided wave direction.

When it is assumed that the seed beam has a unimodal spectrum, the characteristics of the seed beam to be controlled are the peak intensity, peak wavelength, and peak width.

The peak intensity may be controlled using the second electrode 103 because it is easily adjustable. The peak wavelength and peak width are determined by the two types of gratings 115 and 116.

If beams emitted at the first electrode 102 and the second electrode 103 have similar spectra, a peak portion of the beam at the second electrode 103 may be reflected or absorbed by the grating section 105.

That is, the two types of gratings for reflecting or absorbing a beam having the peak wavelength may be disposed.

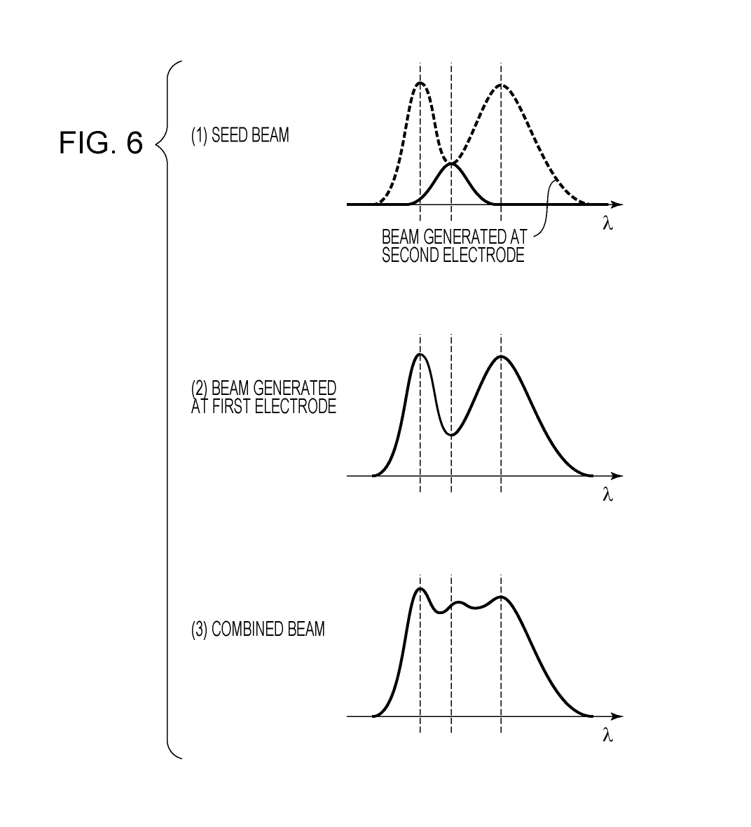

FIG. 6 includes illustrations for describing advantages according to the present exemplary embodiment.

As illustrated in (1) of FIG. 6, a beam generated at the second electrode 103 is emitted from at least two different levels, and their corresponding peaks are present.

As the grating section 105, for example, two types of gratings may be set such that their wavelengths to be reflected or absorbed match with the locations corresponding to the emission peaks.

Thus the seed beam has a peak in a wavelength at which the intensity is low (dip portion) in the spectrum of the beam generated at the first electrode 102.

The degree of a change in image quality depending on the spectral shape can be determined by calculation based on point spread function (PSF).

It is desired that the spectral shape be unimodal, ideally, have a Gaussian function shape. In actuality, there is a deviation from that shape.

That deviation increases side lobes, and it is necessary to reduce the deviation to a small value.

According to Japanese Patent Laid-Open No. 2007-212428, when the side lobes are reduced to no more than −10 dB, noise in an application to OCT measurement can be lowered. This leads to acquirement of optical tomographic images with high resolution.

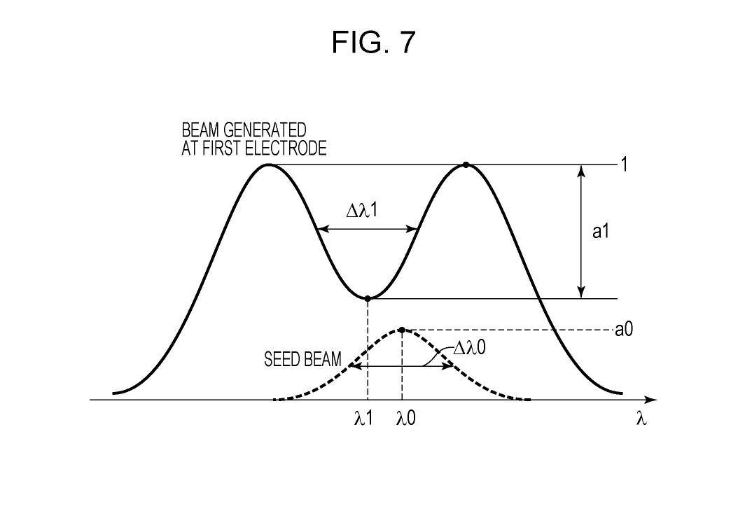

Parameters necessary as the conditions for the seed beam are described with reference to FIG. 7.

The spectrum of the beam generated at the first electrode has the plurality of peaks, and the dip is present between the emission levels.

To complement the dip using the seed beam, it is necessary to specify the peak intensity, peak wavelength, and peak width of the seed beam.

In particular, to reduce the side lobes to no more than −10 dB, it is necessary to limit their values in the seed beam to a certain range.

Here, the simplest case, in which the dip between the two peaks are complemented, is discussed.

It is assumed that the two peak intensities be the same and the two peak widths be the same. The distance between the two peak wavelengths is assumed to be in the range of 20 nm to 80 nm, where a dip tends to occur in a typical spectrum.

The most effective seed beam for complementing the dip is obtainable when the following expressions are satisfied.

a0=a1/exp(g·L1)

λ0=λ1

Δλ0=Δλ1

where λ1 indicates the wavelength at the minimum intensity between the two peak wavelengths, a1 indicates the depth of the dip to the peak intensity of the beam generated at the first electrode, Δλ1 indicates the width of the dip, a0 indicates the peak intensity of the seed beam to the peak intensity of the beam generated at the first electrode, λ0 indicates the peak wavelength of the seed beam, Δλ0 indicates the peak width of the seed beam, g indicates the gain at the first electrode, and L1 indicates the cavity length in the first electrode.

These values are set as reference values. The side lobes can be reduced to no more than −10 dB by confining these values to the ranges described below with respect to their respective reference values.

0.95a1/exp(g·L1)≦a0≦1.31a1/exp(g·L1)

0.98λ1≦λ0≦1.02λ1

0.83Δλ1≦Δλ0≦1.10

[symbol]

λ0 is represented as a value to Δλ0. The ranges of the parameters described above are based on the case where the difference between the highest value and the lowest value of the combined beam spectrum between the two peaks be less than 10%. It is assumed that the parameters other than the changed parameters remain unchanged.

For example, when the difference between the highest value and the lowest value of the combined beam spectrum between the two peaks is reduced to 15% under the above-described conditions, the side lobes can be lowered to the order of 10%.

Then, a procedure for fabricating an actual sample is described below.

First, the n-type clad layer 108, active layer 101, p-type clad layer 109, and contact layer 110 are sequentially caused to grow on the GaAs substrate 107 using, for example, the metal organic chemical vapor deposition (MOCVD) method.

The ridge portion 111 is formed on a wafer in which the layers are stacked using a typical semiconductor lithography method and semiconductor etching.

For example, after a dielectric layer made of, for example, silicon dioxide, is formed by sputtering, a stripe forming mask for forming a ridge with a photoresist using the semiconductor lithography method is produced.

The semiconductor portions other than the strip forming mask are selectively removed using the dry etching method.

At this time, the portions are not fully removed from the p-type clad layer 109, and the ridge shape having a depth of, for example, 0.8 μm is formed.

The ridge portion 111 is tilted by approximately seven degrees with respect to a perpendicular line to the ridge end face and the longitudinal direction of the ridge to prevent reflection at the ridge end face of the ridge portion 111. The end face may be overlaid with a multilayer dielectric to control reflectance.

Then, a dielectric layer made of, for example, silicon dioxide is formed on the semiconductor surface. The silicon dioxide layer is partly removed from the upper portion of the ridge portion 111 by the photolithographic method and wet etching. After that, the upper electrode 113 is formed using the vacuum deposition method and lithographic method. The upper electrode 113 may be made of, for example, titanium/gold (Ti/Au).

Furthermore, the contact layer 110 in the electrode separating region 104 is removed by wet etching. After that, the desirably designed grating section 105 is formed in the electrode separating region 104 by the photolithographic method and wet etching.

Before the formation of the lower electrode 114, the GaAs substrate 107 is thinned to the order of 100 μm by grinding.

Then, the lower electrode 114 is formed using the vacuum deposition method. The lower electrode 114 may be made of, for example, gold-germanium/nickel/gold (AuGe/Ni/Au). To achieve satisfactory electric characteristics, annealing is performed in an atmosphere of high-temperature nitrogen, and the electrodes and semiconductor are alloyed with each other. Finally, a crystal face is exposed through the end face by cleavage, and the sample is completed.

Next, results of a measurement in the present exemplary embodiment are described below.

The measurement is conducted in mode equivalent to the present exemplary embodiment. The length of the first electrode is 0.25 mm. The length of the second electrode is 0.2 mm. The ridge width is 3 μm. For the first grating, the Bragg wavelength is 823 nm, the grating period is 124 nm, the number of periods is 90, the effective refractive indices are 3.35 and 3.29, the height of irregularities is 336 nm, and the duty is 0.5. For the second grating, the Bragg wavelength is 846 nm, the grating period is 127 nm, the number of periods is 90, the effective refractive indices are 3.35 and 3.29, the height of irregularities is 336 nm, and the duty is 0.5.

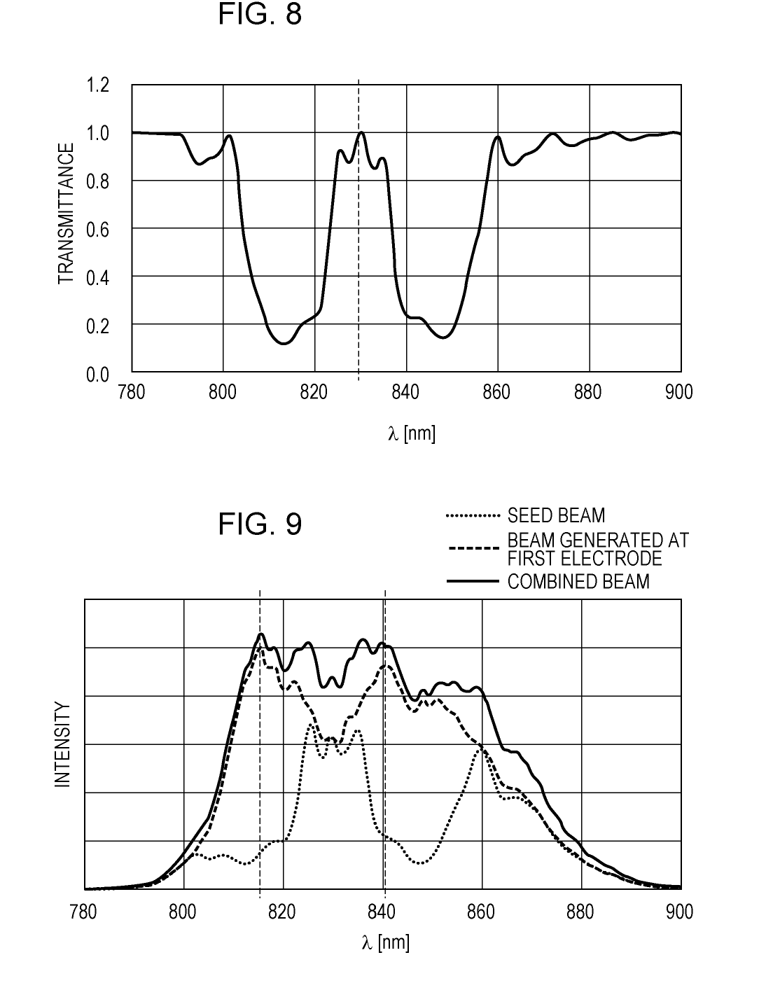

FIG. 8 illustrates a transmittance spectrum in the above-described gratings.

With these gratings, the seed beam can be set as follows:

λ0=830 nm

Δλ0=14 nm

FIG. 9 illustrates spectra of the seed beam, the beam generated at the first electrode, and the combined beam. The magnitude of the seed beam is adjusted as the magnitude when the beam generated at the first electrode is the beam generated at the second electrode.

Combining the seed beam with the beam generated at the first electrode enables the dip between the two peaks to be reduced from 40% to 13%. Thus the spectral shape can be made satisfactory without attenuating the output.

The forming method and the materials of the semiconductor, the electrodes, and the dielectric are not limited to the ones disclosed in the above embodiments. Other methods and materials may also be used without departing from the scope of the invention.

For example, a p-type GaAs substrate may also be used as the substrate. In that case, the conductive type of each semiconductor layer is changed correspondingly.

The active layer adopts a single quantum well structure. In this case, it is necessary to make the well deep or narrow in order to have a plurality of levels. Instead, a multiple quantum well structure having quantum wells with different depths (asymmetric quantum well structure) may also be used.

The materials are also not limited to the above-described ones. Other light emitting materials, such as GaAs, GaInP, AlGaInN, AlGaInAsP, and AlGaAsSb, may also be used.

The ridge width is not limited to 3 [symbol] and may be different values.

The SLD described above has a structure that has a ridge and a tilt. The SLD may have any structure that enables itself to operate as the SLD. For example, the end face may be overlaid with a multilayer dielectric to suppress the reflectance.

The emitting end is described as being next to the active region. An absorption region (window region) where no voltage is applied may be disposed between the active region and the emitting end to suppress optical reflection at the emitting end.

The gratings may not be disposed in the upper portion of the ridge if the above-described advantages are obtainable. For example, the gratings may be disposed in the side surface of the ridge or the upper or lower portion of the active layer. In the present exemplary embodiment, the two types of gratings are used. The number of types is not limited to two.

The number of types of gratings may be more than two. The period intervals, the numbers of periods, and the effective refractive indices may not be uniform in the guided wave direction.

The electrodes in the sample are two separate electrodes. The electrodes may be more than two separate electrodes before and after the gratings.

The electrodes may operate under the same driving condition in the range where the above-described conditions are satisfied.

Here, parameters of the gratings at which the advantages in the present exemplary embodiment are provided are described. In the present exemplary embodiment, the gratings with Bragg wavelengths of 823 nm and 846 nm are described as examples. Adjustment may be made by changing the grating periods. In the present exemplary embodiment, the gratings are formed between the electrodes to adjust the spectrum of the seed beam. If the distance between the electrodes is long, optical absorption is large in the portion therebetween. Thus it is necessary to set the distance between the electrodes to 20 μm at the longest. In this case, when the other parameters of each of the gratings are equal, the Bragg wavelength can be extended up to 1475 nm. If the number of periods is increased, the wavelength selectivity for transmitting light is improved, but this leads to an increase in the distance between the electrodes, as in the case of the Bragg wavelength. When the distance between the electrodes is 20 μm, the number of periods can be increased up to approximately 150. If the difference between the effective refractive indices, which are 3.35 and 3.29 in the above exemplary embodiment, is increased, the wavelength selectivity for transmitting light is improved. In the present exemplary embodiment, the height of the irregularities of the grating is 336 nm. If it is 518 nm, the difference between the effective refractive indices can be extended up to 0.15. The duty may be 0.5. Even if there is a deviation of ±0.05, the characteristics do not significantly deteriorate.

The spectral shape can be corrected more efficiently by changing the parameters of the gratings, adjusting the Bragg wavelengths and the wavelength selectivity for transmitting light, and fitting them to the dip shape in the spectrum of the beam generated at the first electrode. The transmittance spectrum may be adjusted by changing the above parameters. In place of the rectangular gratings, which are described as an example in the present exemplary embodiment, gratings with refractive indices gradually varying in the guided wave direction, for example, in the shape of a sawtooth or a sine wave may be used. A configuration in which the refractive indices are changed by changing the material of the active layer in the guided wave direction may also be used.

### Second Exemplary Embodiment

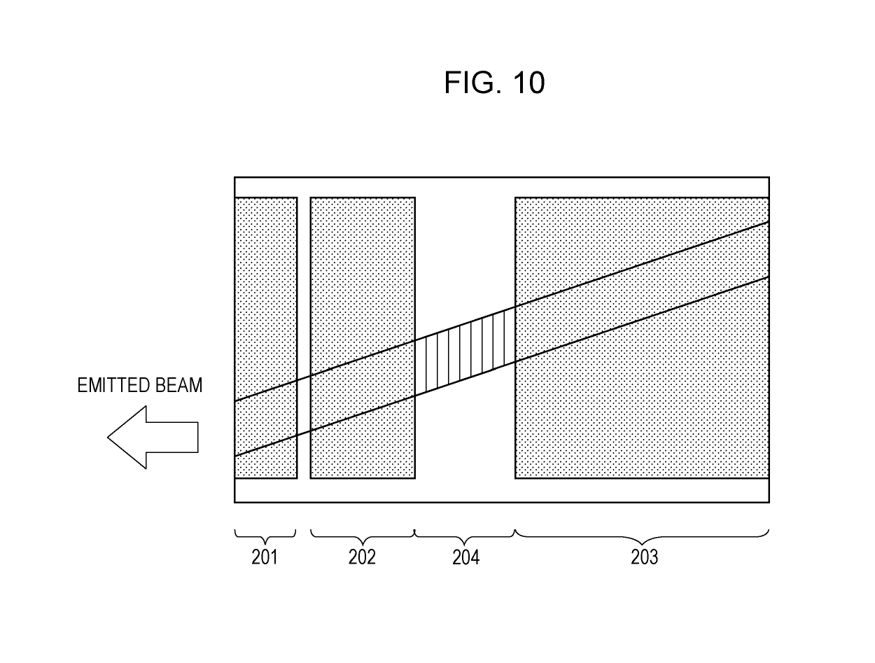

An example configuration of the SLD different from the first exemplary embodiment is described as a second exemplary embodiment with reference to FIG. 10.

The present exemplary embodiment is characteristic in that it has a configuration in which the first electrode includes a plurality of electrodes separated in the guided wave direction. The electrodes are referred to as a first A electrode 201, a first B electrode 202, . . . , in sequence from the one nearest the emitting end.

A sample including only the first electrode is discussed. If the first electrode is not separated, main emission peaks are at adjacent levels. In the present exemplary embodiment, when the current density in each electrode is changed, emission peaks at remote levels can be achieved.

In that case, high power emission that has a wider spectrum width than that in the case where the electrode is not separated is obtainable. However, because the emission between the levels is weak and the wavelength difference between the peaks is large, the spectral shape significantly deteriorates.

Accordingly, a high-power combined beam with a wider band and a satisfactory shape can be acquired in the present exemplary embodiment by complementing the dip between the two peaks, as in the first exemplary embodiment.

### Third Exemplary Embodiment

Another example configuration of the SLD different from the first exemplary embodiment is described as a third exemplary embodiment.

Because the first exemplary embodiment aims to complement the dip between the two peaks, ideally, all of light with wavelengths other than the ones between the two gain peaks should be reflected or absorbed by the gratings.

The present exemplary embodiment aims to complement the dip between the two peaks and further extend the wide band of an emission spectrum of a combined beam.

Specifically, these aims can be achieved by narrowing the wavelength band range of light reflected or absorbed by the gratings from that in the first exemplary embodiment.

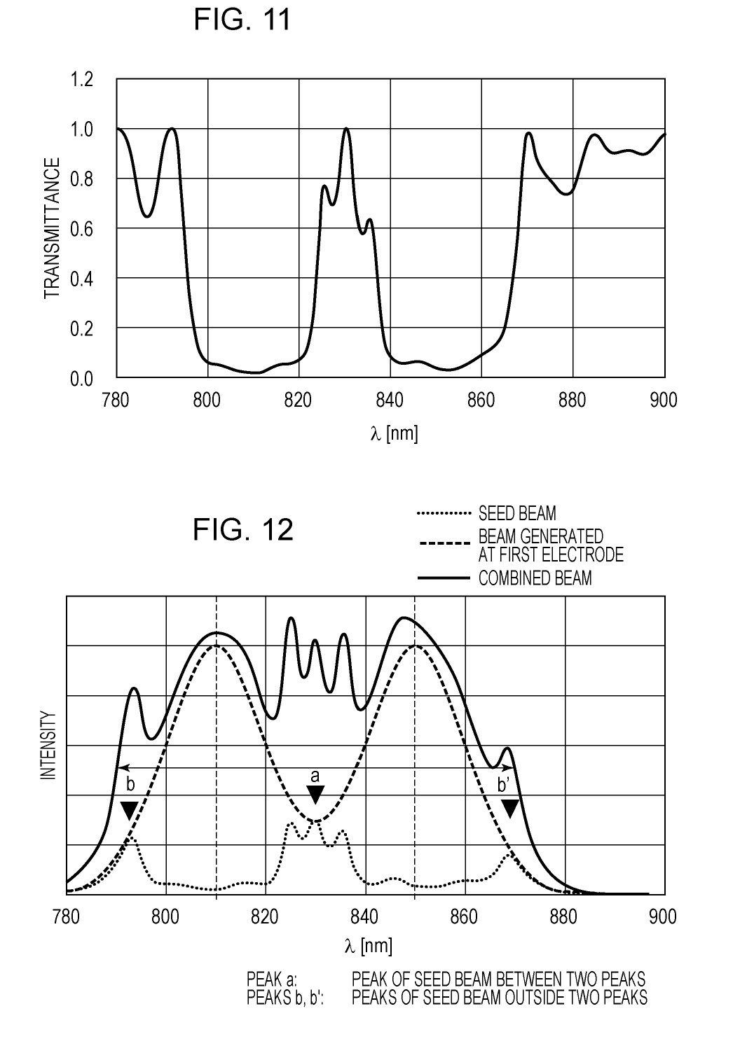

FIG. 11 illustrates a transmittance spectrum in the gratings used in the present exemplary embodiment. FIG. 12 illustrates spectra of the seed beam, the beam generated at the first electrode, and the combined beam in the present exemplary embodiment. The magnitude of the seed beam is adjusted as the magnitude when the beam generated at the first electrode is the beam generated at the second electrode.

Here, it is assumed that the spectrum is a combination of two Gaussian functions of the beams generated at the first and second electrodes each having a peak-to-peak distance of 40 nm.

When for the first grating, the Bragg wavelength is 810 nm, the grating period is 123 nm, the number of periods is 70, the effective refractive indices are 3.35 and 3.25, the height of irregularities is 430 nm, and the duty is 0.5 and for the second grating, the Bragg wavelength is 850 nm, the grating period is 129 nm, the number of periods is 70, the effective refractive indices are 3.35 and 3.25, the height of irregularities is 430 nm, and the duty is 0.5, in addition to a peak (peak a) between the two peaks, peaks (b, b′) outside the peaks other than the dip portion between the two peaks (on the shorter-wavelength side of the shorter-wavelength peak and on the longer-wavelength side of the longer-wavelength peak) are also observed in the seed beam.

As a result, in addition to the advantages of complementing the dip between the two peaks, the full width at half maximum of the combined beam spectrum can be improved by 23% from 64 nm to 79 nm.

### Fourth Exemplary Embodiment

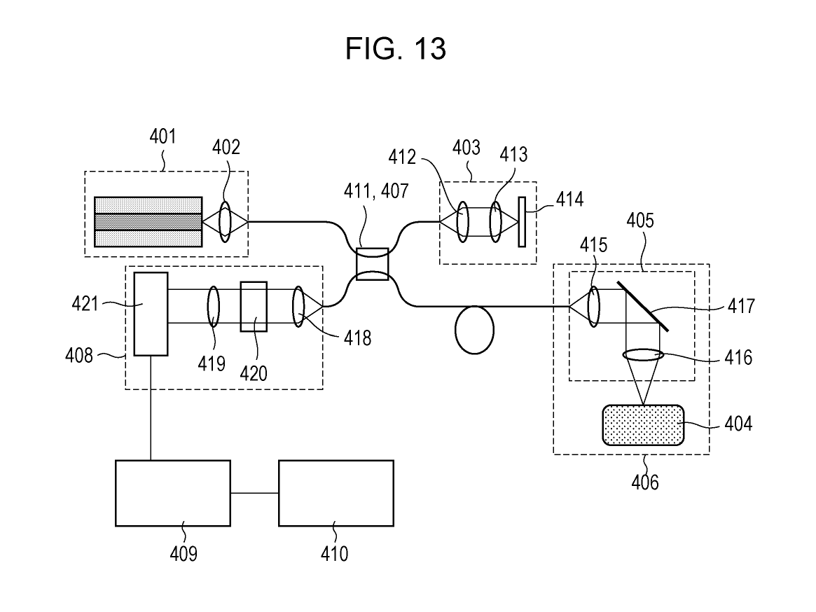

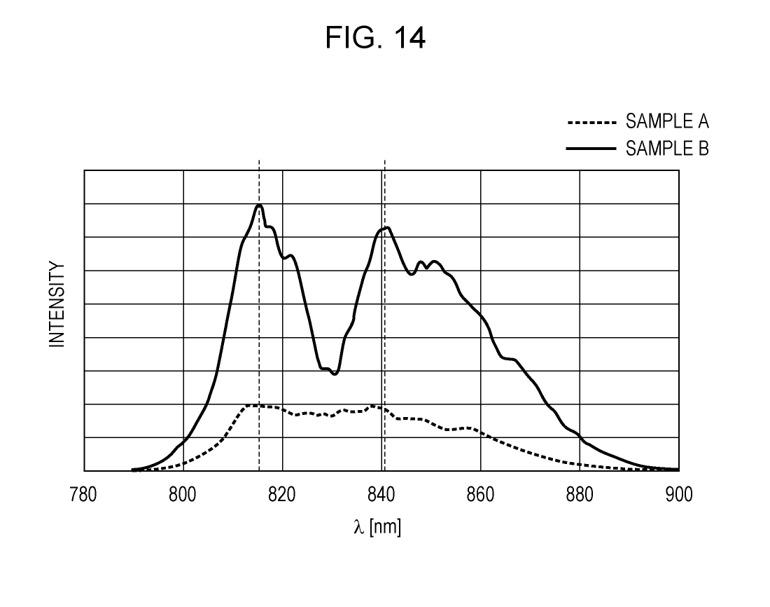

An example configuration of an optical coherence tomography apparatus including the SLD according to the present invention as a light source is described as a fourth exemplary embodiment with reference to the schematic diagram of FIG. 13.

As illustrated in FIG. 13, the OCT apparatus according to the present exemplary embodiment includes a light dividing unit 411 configured to divide light emitted from a light outputting unit 401 into a reference beam and a measurement beam, a reference beam reflecting unit 403, and a measuring unit 406 including a measurement object 404 and an irradiation optical system 405 configured to irradiate the measurement object 404 with light.

The OCT apparatus further includes an interference unit 407 configured to cause a reflected reference beam and a reflected measurement beam to interfere with each other, a light detecting unit 408 configured to detect an interference beam acquired by the interference unit 407, an image processing unit 409 configured to perform image processing on light detected by the light detecting unit 408 (acquire a tomographic image), and an image output monitor unit 410.

As the light outputting unit 401, the SLD according to the first exemplary embodiment is used.

Light traveling through an optical fiber is divided into a reference beam and a measurement beam by the light dividing unit 411. A portion of the divided light enters the reference beam reflecting unit (reference unit) 403 configured to transmit a reflected beam from a reference mirror. The light dividing unit 411 and the interference unit 407 use the same fiber coupler.

The reference beam reflecting unit 403 includes collimator lenses 412 and 413 and a reflector (reference mirror) 414 and is configured to reflect a beam at the reflector 414 and input it into the optical fiber again.

The measurement beam, which is the other one of the beams in which light is divided by the light dividing unit 411, enters the measuring unit (specimen measuring unit) 406 configured to transmit a beam reflected from the measurement object (specimen) through the optical fiber.

The irradiation optical system 405 in the measuring unit 406 includes collimator lenses 415 and 416 and a reflector 417 configured to bend an optical path by 90 degrees.

The irradiation optical system 405 serves to cause an input beam to be incident on the measurement object 404 and cause a reflected beam to reenter the optical fiber.

The beams returning from the reference beam reflecting unit 403 and the measuring unit 406 pass through the interference unit 407 and enter the light detecting unit 408.

The light detecting unit 408 includes collimator lenses 418 and 419 and a line sensor 421 configured to acquire information on spectral components of light separated by a spectroscope 420. The spectroscope 420 uses a grating.

The light detecting unit 408 is configured to acquire information on spectral components of received light.

The information acquired in the light detecting unit 408 is converted into an image in the image processing unit 409 configured to convert information into a tomographic image, and tomographic image information being final output is obtained. This information is displayed as a tomographic image on the image output monitor unit 410, which may be a display area of a personal computer or the like.

One characteristic of the present exemplary embodiment is the light outputting unit 401. Because the use of the SLD described in the above-described embodiments enables a broadband spectrum to be output, tomographic image information with high depth resolution can be acquired. The OCT apparatus is useful for taking tomographic images in medical facilities, including an ophthalmology department, a dermatology department, and a dental clinic.

The present invention can provide a superluminescent diode capable of achieving both a wide band and high power and acquiring a satisfactory unimodal spectral shape and an optical coherence tomography apparatus including the superluminescent diode as a light source.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-200129, filed Sep. 26, 2013, which is hereby incorporated by reference herein in its entirety.

What is claimed is:

1. A light emitting device comprising:
an optical waveguide including an active layer disposed above a substrate and a pair of clad layers sandwiching the active layer; and
electrodes disposed in a guided wave direction of the optical waveguide,
wherein the light emitting device drives the electrodes and emits a beam guided to the optical waveguide through an emitting end of the optical waveguide,
the active layer has at least two gain peaks,
the electrodes include a first electrode nearest the emitting end and a second electrode next to the first electrode,
the light emitting device further includes a grating section disposed in a vicinity of the optical waveguide and located between the first and second electrodes,
the grating section is set so as to reflect or absorb a beam having a wavelength other than wavelengths in a portion between the two gain peaks in a spectrum of the beam generated by driving the second electrode,
the beam generated by driving the second electrode and having the wavelength selected by the grating section is guided to a region of the optical waveguide where the first electrode is disposed and is combined with a beam generated by driving the first electrode, and
the light emitting device emits a beam having a peak in a dip portion between the two gain peaks in a spectrum of the beam generated by driving the first electrode through the end face.

2. The light emitting device according to claim 1, wherein
the beam generated by driving the second electrode and having the wavelength selected by the grating section has a magnitude substantially equal to
a magnitude of the beam in the dip portion between the two gain peaks in the spectrum of the light generated by driving the first electrode.

3. The light emitting device according to claim 1, wherein
when a peak intensity of the beam after the beam generated by driving the second electrode passes through the grating section is a0, a peak wavelength thereof is λ0, a peak width thereof is Δλ0,
a peak intensity of the beam generated by driving the first electrode is 1, a wavelength at a minimum intensity between the two peak wavelengths in the spectrum of the light is λ1, a depth of the dip between the two gain peaks in the spectrum of the light is a1, and a width of the dip between the two gain peaks in the spectrum of the light is Δλ1,
0.95a1≦a0≦1.31a1
0.98λ1≦λ0≦1.02λ1
0.83Δλ1≦Δλ0≦1.10Δλ1

4. The light emitting device according to claim 1, wherein
a current density in the second electrode is set at a density of a current produced by the beam in the two gain peaks in the spectrum of the light generated by driving the second electrode.

5. The light emitting device according to claim 1, wherein
the grating section includes two or more types of gratings.

6. The light emitting device according to claim 5, wherein
the gratings have different period intervals, different numbers of periods, and different effective refractive indices.

7. The light emitting device according to claim 6, wherein
each of the gratings has a structure in which the period interval is not uniform in the guided wave direction of the optical waveguide.

8. The light emitting device according to claim 1, wherein
the active layer having the plurality of gain peaks has a quantum well structure with a plurality of emission levels.

9. The light emitting device according to claim 1, wherein
the active layer having the plurality of gain peaks has an asymmetric quantum well structure with different emission levels.

10. The light emitting device according to claim 1, wherein
the first electrode includes a plurality of electrodes separated in the guided wave direction.

11. The light emitting device according to claim 1, wherein
the beam generated by driving the second electrode and having the wavelength selected by the grating section has
a peak in a portion other than the dip portion between the two gain peaks in the spectrum of the light generated by driving the first electrode.

12. An optical coherence tomography apparatus comprising:
a light source including the light emitting device according to claim 1;
a specimen measuring unit configured to irradiate a specimen with a beam from the light source and transmit a beam reflected from the specimen;
a reference unit configured to irradiate a reference mirror with the beam from the light source and transmit a beam reflected from the reference mirror;
an interference unit configured to cause the reflected beam from the specimen measuring unit and the reflected beam from the reference unit to interfere with each other to acquire an interference beam;
a light detecting unit configured to detect the interference beam from the interference unit; and
an image processing unit configured to acquire a tomographic image of the specimen based on the beam detected by the light detecting unit.
